(19) United States
(12) Patent Application Publication
(10) Pub. No.: US 2002/0106888 A1
(43) Pub. Date: Aug. 8, 2002

(54) Process for manufacturing an electronic semiconductor device with improved insulation by means of air gaps

(75) Inventors: Omar Vassalli, Pradalunga (IT); Massimiliano Gullotta, Arese (IT)

Correspondence Address: SEED INTELLECTUAL PROPERTY LAW GROUP PLLC, 701 FIFTH AVE, SUITE 6300, SEATTLE, WA, 98104-7092, US

(73) Assignee: STMicroelectronics S.r.I., Agrate Brianza (IT)

(21) Appl. No.: 10/006,923

(22) Filed: Dec. 4, 2001

(30) Foreign Application Priority Data
Dec. 5, 2000 (IT) TO2000A 001134

(51) Int. Cl. H01L 21/4763; H01L 21/31; H01L 21/469

(52) U.S. Cl. 438/618; 438/780

(57) ABSTRACT

A process that includes forming a metal layer on top of a wafer of semiconductor material; forming a mask having an appropriate geometry; defining the metal layer to form conductive lines in the metal layer according to the geometry of the mask; forming, on side walls of the mask a polymeric structure; selectively removing the mask; depositing, on the polymeric structure and on the conductive lines, an insulating material. The polymeric structure, made of an inorganic polymer, forms a “supporting bridge” for the insulating material, preventing the latter from depositing in the gaps between the conductive lines. In these conditions, the gap between two adjacent conductive lines is occupied only by air, which has a very low dielectric constant. This results in a reduced capacitive coupling between the lines themselves.

### BACKGROUND OF THE INVENTION

1. Field of the Invention

The present invention relates to a process for manufacturing an electronic semiconductor device with improved insulation by means of air gaps.

2. Description of the Related Art

As is known, electronic semiconductor devices are provided with conductive structures (lines, etc.) that form electrical connections between the various components making up the devices themselves. The conductive structures are made on the surfaces of the electronic devices, using electrically conductive materials, such as aluminum, copper, etc.

In this connection, FIG. 1 shows a cross section, at an enlarged scale, of an electronic semiconductor device 1 comprising a silicon substrate 2 and a silicon-dioxide layer 3, set on top of the substrate 2. Formed on the top surface 3a of the silicon-dioxide layer 3 are conductive structures 4, in particular conductive lines, which have a basically rectangular shape in the cross-sectional view of FIG. 1. The conductive lines 4 are surrounded on the top and at the sides by an insulating material 5. Generally, the insulating material is silicon dioxide.

As the pitch between the conductive lines decreases, as a result both of a decrease in the size of electronic devices and of the evolution of the corresponding integration processes, there is an increasing likelihood of capacitive coupling being set up between adjacent conductive lines, the said coupling generating interference between the electrical signals that traverse the lines.

In order to overcome the above-mentioned drawback, a first known solution envisages the use of insulating materials other than silicon dioxide for insulation of the conductive lines from one another. In greater detail, FIG. 2 illustrates an integrated electronic device 1a, which is similar to the electronic device 1 of FIG. 1, except for the fact that the conductive lines 4 are surrounded at the top and at the sides by an insulating material 6 having a dielectric constant lower than that of the silicon dioxide. In this way, the capacitive coupling between adjacent conductive lines is reduced, as is also any interference between the electrical signals traversing the said lines.

In order to reduce the capacitive coupling even further, a second known solution envisages the formation of air gaps between adjacent conductive lines. In greater detail, FIG. 3 shows an integrated electronic device b similar to the electronic device 1a of FIG. 2, except for the presence of a first air gap 7a and a second air gap 7b, which are formed during deposition of the insulating material 6. In particular, the air gap 7a extends in the insulating material 6 starting from the top surface 3a of the silicon-dioxide layer 3 and is arranged between a first pair of adjacent conductive lines 4a, 4b, from which it is separated by means of first portions 6a, 6b of the insulating material 6. Likewise, the air gap 7b extends in the insulating material 6 starting from the top surface 3a of the silicon-dioxide layer 3 and is arranged between a second pair of adjacent conductive lines 4b, 4c, from which it is separated by means of second portions 6c, 6d of the insulating material 6. Since the air gaps 7a, 7b have a dielectric constant lower than that of the insulating material 6, capacitive coupling, and hence any interference between the electrical signals that traverse the conductive lines 4a, 4b, 4c, prove to be considerably reduced as compared to the case in which insulation between the lines is obtained by means of the insulating material 6 alone (FIG. 2).

However, the demand on the market for electronic devices with ever smaller dimensions leads to an increase in the capacitive coupling between adjacent conductive lines and hence in interference between the electrical signals that traverse said lines.

### BRIEF SUMMARY OF THE INVENTION

The disclosed embodiments of the present invention provide a process for manufacturing an electronic semiconductor device that makes it possible to obtain a better insulation by means of air gaps as compared to known solutions, in such a way that, whatever the size of the electronic device, the electronic device is free from the limitations referred to above.

According to the present invention a process is provided that includes forming a conductive layer on top of a wafer of semiconductor material; forming a mask; defining the conductive layer to form conductive lines; forming a polymeric structure on sidewalls of the mask; selectively removing the mask without removing the polymeric structure; and depositing a layer of insulating material on the polymeric structure and on the conductive lines.

In accordance with another embodiment of the invention, an electronic device is provided that includes a wafer of semiconductor material; conductive lines extending on top of the wafer; a layer of insulating material extending over the conductive lines; and a polymeric structure extending between the conductive lines and the layer of insulating material to form air gaps between the conductive lines.

### BRIEF DESCRIPTION OF THE SEVERAL VIEWS OF THE DRAWING(S)

For a better understanding of the present invention, preferred embodiments thereof are now described, purely to provide non-limiting examples, with reference to the attached drawings, in which:

FIG. 1 is a cross-sectional view, at an enlarged scale, of a first embodiment of a known electronic semiconductor device;

FIG. 2 is a cross-sectional view, at an enlarged scale, of a second embodiment of the device of FIG. 1;

FIG. 3 is a cross-sectional view, at an enlarged scale, of a third embodiment of the device of FIG. 1;

FIGS. 4 to 7 are cross-sectional views, at an enlarged scale, of a silicon wafer in successive steps of a process for manufacturing an electronic semiconductor device according to the invention; and

FIGS. 8 and 9 are cross-sectional views, at an enlarged scale, of a silicon wafer in two successive manufacturing steps according to a different embodiment of the process in accordance with the invention.

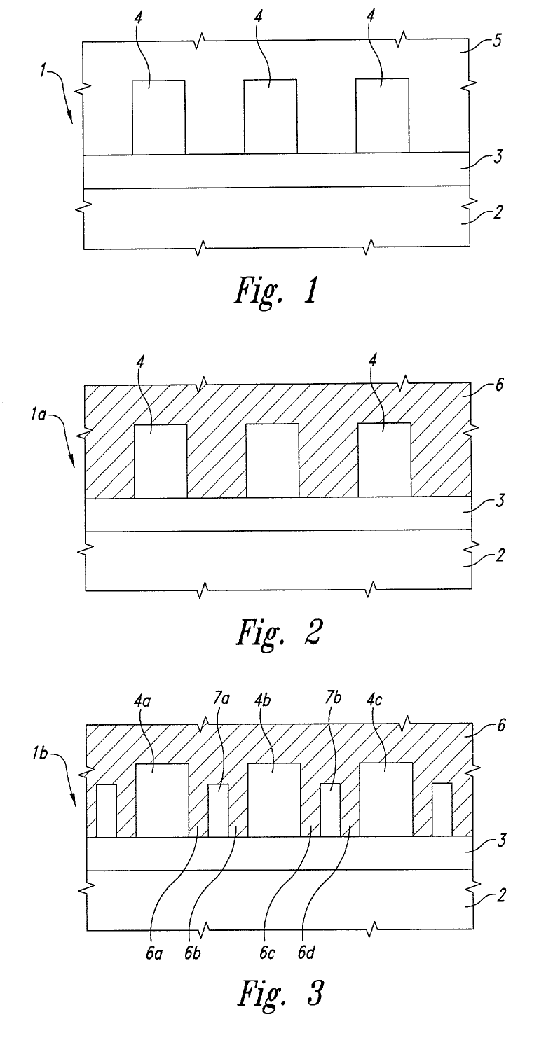

### DETAILED DESCRIPTION OF THE INVENTION

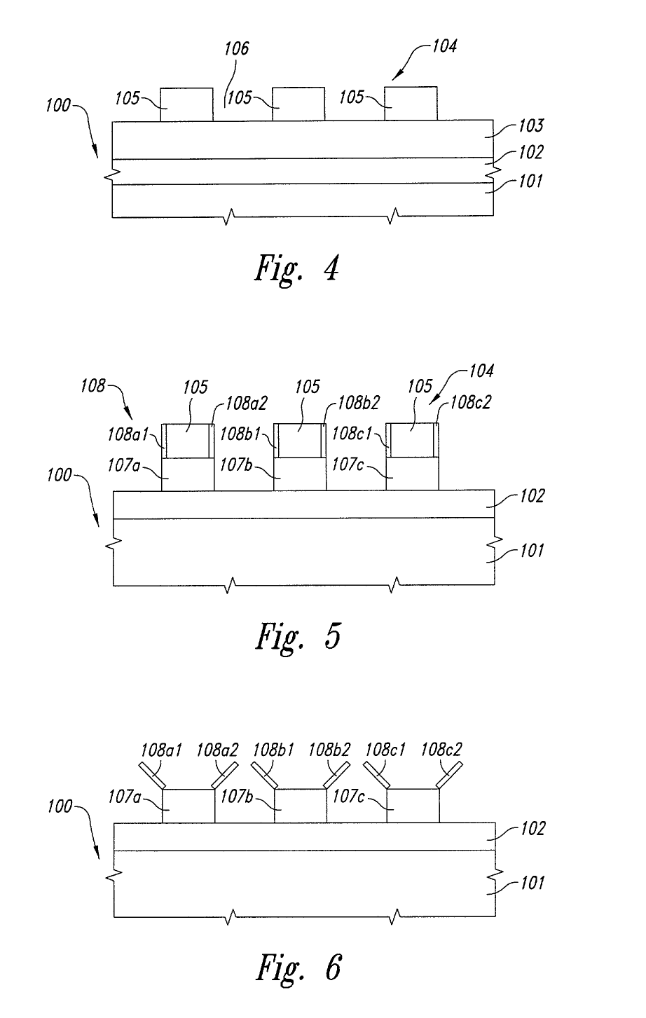

FIG. 4 is a schematic illustration of a wafer 100 formed by a silicon substrate 101 on which a silicon-dioxide layer 102 is grown. On top of the silicon-dioxide layer 102, a metal layer 103 to be etched is deposited.

On the metal layer 103, a mask 104 of non-conductive material (for example, resist) is formed which has a geometry comprising mask regions 105 delimited by openings 106. The openings 106 leave portions of the metal layer 103 uncovered.

Using the mask 104, plasma etching is carried out to remove the uncovered regions (i.e., the ones facing the openings 106) of the metal layer 103, in such a way as to define conductive structures, namely conductive lines 107a, 107b, 107c, each of which has a basically rectangular shape in the cross-sectional view of FIG. 5.

During plasma etching, on the side walls of each mask region 105 there is formed naturally a polymeric structure 108 consisting of an inorganic polymer that includes metal ions and silicon ions respectively coming from the metal layer 103 and from the silicon-dioxide layer 102 (FIG. 5). In detail, the polymeric structure 108 is formed by a plurality of arms 108a1, 108a2, 108b1, 108b2, 108c1, 108c2, two for each conductive line 107a-107c, which extend upwards starting from respective top edges of the respective conductive line 107a-107c, at the sides of the mask regions 105.

Next, the mask 104 is removed using an oxygen plasma. Unlike what occurs in known processes, and in accordance with an aspect of the present invention, the polymeric structure 108 is not removed. Consequently, since the pairs of arms 108a1, 108a2, 108b1, 108b2, 108c1, 108c2 are no longer supported by the mask regions 105, they bend laterally under their own weight, in such a way that the arms 108a1, 108a2, 108b1, 108b2, 108c1, 108c2 of each pair diverge from one another. In this way, the adjacent arms 108a2, 108b1 and 108b2, 108c1, which are supported by adjacent conductive lines 107a-107c, converge towards one another and close at the top, at least in part, the gap between the conductive lines 107a-107cthemselves, as shown in FIG. 6.

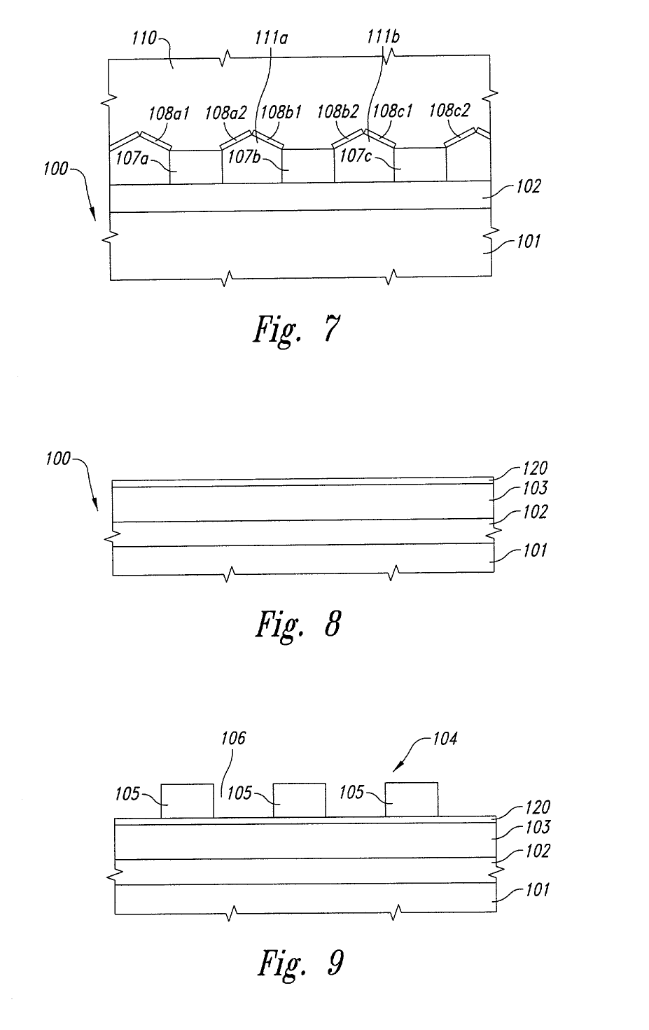

Subsequently, a layer 110 of insulating material, for example silicon dioxide, is deposited on the top surface 110a of the wafer 100. In these conditions, the polymeric structure 108 forms a “bridge” which supports the layer 110 of insulating material (FIG. 7). In this way, the polymeric structure 108 prevents the layer 110 of insulating material from being deposited in the gaps between the conductive lines 107a-107c, forming, respectively, a first air gap 111a and a second air gap 111b.

In greater detail, the first air gap 111a is delimited laterally by the adjacent conductive lines 107a and 107b, at the bottom by the silicon-dioxide layer 102, and at the top by the arms 108a2, 108b1 of the polymeric structure 108. Likewise, the second air gap 111b is delimited laterally by the adjacent conductive lines 107b and 107c, at the bottom by the silicon-dioxide layer 102, and at the top by the arms 108b2, 108c1 of the polymeric structure 108.

In these conditions, the air gap 111a occupies completely (and not partially as in known devices) the gap between the adjacent conductive lines 107a and 107b. Likewise, the air gap 111b occupies completely the gap between the conductive lines 107b and 107c.

Advantageously, since the air gaps 111a, 111b have a dielectric constant lower than that of the insulating material 110, they considerably reduce the capacitive coupling between the adjacent conductive lines 107a and 107b and, respectively, 107b and 107c, and consequently considerably reduce any interference between the electrical signals that traverse the said lines.

With reference to FIGS. 8 and 9, the polymeric structure 108 may also be obtained by sputtering. In this case, a substrate layer 120, obtained using silicon dioxide (SiO₂) or silicon oxynitride (SiON), is deposited on top of the metal layer 103 (FIG. 8). Next, on top of the substrate layer 120, the mask 104 comprising the mask regions 105 is formed (FIG. 9). The substrate layer 120 is then subjected to intense ion bombardment, which may be performed, for example, using a plasma obtained with an inert gas (for instance, Ar, He, or N₂) inside an implanter. In this way, the substrate layer 120 is sputtered on the side walls of the mask regions 105 to form the polymeric structure 108, as shown in FIG. 7.

The substrate layer 120 may also be obtained as follows:

by plasma deposition, using normal plasma-deposition techniques;

by chemical vapour deposition (CVD), using an appropriate chemical reaction; and

by indirect sputtering. In the latter case, the wafer 100 as shown in FIG. 4 is put in an etching chamber at the top of which there is present a substrate disk. When the disk is subjected to plasma etching, the ions of the substrate drop, depositing on the side walls of the mask regions 105 to form the polymeric structure 108.

In any case, whatever the technique employed for obtaining the polymeric structure 108, the latter must not be removable by an oxygen plasma (which is used to remove the mask 104).

The advantages of the manufacturing process according to the present invention emerge clearly from the foregoing description. In particular, it is emphasized that the process according to the invention makes it possible to reduce considerably, and even to eliminate, the capacitive coupling between adjacent conductive lines, also thanks to the fact that the gap between the said lines is completely occupied by air, which has a very small dielectric constant (smaller than that of any insulating material up to now used).

Finally, it is clear that numerous modifications and variations may be made to the process described herein, without thereby departing from the scope of the present invention. Thus, the invention is to be limited only by the scope of the appended claims and the equivalents thereof.

1. A process for manufacturing an electronic semiconductor device, comprising:
forming a conductive layer on top of a wafer of semiconductor material;
forming a mask;
defining said conductive layer to form conductive lines;
forming a polymeric structure on side walls of said mask;
selectively removing said mask without removing said polymeric structure; and
depositing a layer of insulating material on said polymeric structure and on said conductive lines.

2. The process of claim 1, wherein said polymeric structure comprises an inorganic polymer.

3. The process of claim 2, wherein said polymer comprises metal ions and ions of semiconductor material.

4. The process of claim 1, wherein defining said conductive layer and forming a polymeric structure comprise etching said conductive layer.

5. The process of claim 4, wherein etching said conductive layer is carried out using plasma.

6. The process of claim 1 comprising, before said step of preparing a mask, depositing by sputtering a substrate layer.

7. The process of claim 1 comprising, before preparing a mask, depositing a substrate layer.

8. The process of claim 1 comprising, before preparing a mask, a chemical vapour deposition of a substrate layer.

9. The process of claim 1, wherein depositing an insulating material comprises forming a first air gap and a second air gap, respectively between a first pair of said conductive lines and between a second pair of said conductive lines.

10. The process of claim 1, wherein said conductive layer is made of metal.

11. An electronic device comprising:
a wafer of semiconductor material;
conductive lines extending on top of said wafer;
a layer of insulating material extending over said conductive lines; and
a polymeric structure extending between said conductive lines and said layer of insulating material.

12. The device of claim 11, wherein said polymeric structure comprises a plurality of pairs of polymeric arms, said pairs of polymeric arms each being carried by a respective conductive line.

13. The device of claim 12, wherein said pairs of polymeric arms extend starting from edges of a respective conductive line and diverge with respect to one another.

14. The device of claim 12 wherein the polymeric arms that face one another and are carried by two adjacent conductive lines converge with respect to one another.

15. The device of claim 12 wherein said polymeric arms are made of a polymer of an inorganic type.

16. The device of claim 15, wherein said polymer comprises metal ions and ions of semiconductor material.

17. The device of claim 12 comprising air gaps, each air gap delimited laterally by respective adjacent conductive lines at the top by respective polymeric arms, and at the bottom by said wafer.

18. A process for manufacturing an electronic semiconductor device, comprising:
forming a conductive layer on top of a wafer of semiconductor material;
forming a mask;
defining the conductive layer to form conductive lines;
forming a polymeric structure on sidewalls of the mask;
selectively removing the mask without removing the polymeric structure to form a pair of polymeric arms on each conductive line, the polymeric arms of each conductive line diverging away from each other to connect with the polymeric arms of adjacent conductive lines and forming an air gap between the adjacent conductive lines; and
depositing a layer of insulating material on the polymeric structure and on the conductive lines.

19. An electronic device, comprising:
a wafer of semiconductor material;
conductive lines extending on top of the wafer;
a pair of polymeric arms extending from each conductive line and diverging from each other to connect with polymeric arms of adjacent conductive lines to form an air gap between the adjacent conductive lines; and
a layer of insulating material extending over the conductive lines.

20. A process for manufacturing an electronic semiconductor device, comprising:
forming conductive lines on a conductive layer that is formed on top of a wafer of semiconductor material;
forming a pair of polymeric arms on each conductive line that diverge away from each other and connect with polymeric arms on adjacent conductive lines to form an air gap between adjacent conductive lines; and
depositing a layer of insulating material on the polymeric arms and on the conductive lines to enclose the airgap.
